(19) United States
(12) Patent Application Publication
(10) Pub. No.: US 2025/0324540 A1
(43) Pub. Date: Oct. 16, 2025

(54) ASSEMBLY FOR POWER MODULES AND MOUNTING METHOD FOR THE ASSEMBLY FOR POWER MODULES

(71) Applicant: MAGNA Powertrain GmbH & Co. KG, Lannach (AT)

(72) Inventor: Benjamin Pessl, Linz (AT)

(21) Appl. No.: 18/869,403

(22) PCT Filed: May 15, 2023
(86) PCT No.: PCT/EP2023/062901

§ 371 Date: Nov. 26, 2024

(30) Foreign Application Priority Data
May 30, 2022 (DE) 10 2022 205 362.1

(51) Int. Cl. H05K 7/20

(52) U.S. Cl. CPC H05K 7/20254; H05K 7/20272; H05K 7/20409; H05K 7/20927

(57) ABSTRACT

An assembly for power modules includes at least one power module and a cooling channel having an inlet and an outlet. The cooling channel is formed by a lower half shell and an upper half shell and the power electronics system has cooling fins which protrude into the cooling channel through respective cut-outs. The cooling channel is integrally sealed between the power module and the upper half shell, and the lower half shell and the upper half shell are produced by deep drawing, with at least one bridging piece interconnecting them.

### CROSS-REFERENCE TO RELATED APPLICATIONS

This application is a National Stage of International Application No. PCT/EP2023/062901, filed on May 15, 2023, which claims priority to DE 10 2022 205 362.1, filed on May 30, 2022. The entire disclosures of each of the above applications are incorporated herein by reference.

### FIELD

The present disclosure relates to a structural unit for power modules, including at least one power module, including a cooling channel having an inlet and outlet, wherein the cooling channel is formed by a lower half-shell and an upper half-shell, and the power electronics system has cooling fins that protrude through a cut-out into the cooling channel.

The present disclosure additionally relates to an assembly method for the structural unit for power modules.

### BACKGROUND

The core element of inverters in the automotive sector is a so-called power stack, i.e. power electronics system components in a housing. When the semiconductor switches of the inverter are actuated, switching losses occur that result in heating of the semiconductor switches and of the power module. Each semiconductor switch, or each power module, has a maximum operating temperature. If this maximum operating temperature is exceeded, it is possible that the semiconductor switch, or power module, will be damaged. Consequently, it is necessary for the semiconductor switch, or the power module, or other electronic/electrical components, such as resistors, to be cooled. Passive cooling bodies, for example, made of aluminum and having cooling fins, are used for this purpose.

This housing includes a cooling channel, as well as the power semiconductors required to convert direct current into alternating current. In many cases, the cooling channel is sealed off from the power semiconductors. The power semiconductors are applied to the surface of the cooling channel by way of a suitable method, e.g. by being attached via a thermally conductive material, by soldering or sintering, in order to produce the thermal and mechanical connection. The disadvantage here is that further thermal transitions and conductive paths are introduced between the power module and the coolant and the power semiconductors. This impairs the thermal transition from the heat source to the coolant, and often results in the occurrence of higher temperatures than is the case with direct cooling.

In addition to these designs, there are also power electronics system solutions in which the power semiconductors are already equipped with a prefabricated cooling structure such as fins. This cooling structure protrudes into the coolant flow in order to extract the thermal energy from the power semiconductors. The attachment between the power semiconductor and a cooling channel in the housing is effected by way of a suitable sealing solution, e.g. with an O-ring or a shaped seal. It is also known for a structural unit for power modules to be pressed against the cooling channel by way of specially designed additional components in order to achieve the sealing effect and prevent the structural unit for power modules from being lifted off the cooling channel.

These additional components must be taken into consideration in the entire procurement, handling and assembly process. The seals required disrupt the coolant flow at several sites in a power semiconductor module, resulting both in unnecessary pressure loss and in so-called dead water zones. In these zones in the “shadow” of the sealing sites, there is hardly any coolant exchange, resulting in localized temperature increases.

A further disadvantage of existing solutions is the usually complex geometric design of the cooling channel. There is a high component and assembly complexity, which has a direct impact on costs.

In such a structure, it is also necessary to provide additional elements for fastening the power modules. This includes structures that touch the power modules on one side, as well as fastening elements such as, for example, screws that tension and hold the said structures in place. The overall high level of complexity—in particular due to a plurality of seals including fastening elements—involves a high level of necessary protection measures.

A structural unit for power modules including at least one power module and including a cooling channel having an inlet and outlet is known from DE 10 2022 201 557.6, the cooling channel being formed by a lower half-shell and an upper half-shell, and the power electronics system having cooling fins that protrude through a cut-out into the cooling channel, the cooling channel being closed in a materially bonded manner between the power module and the upper half-shell. The half-shells, however, are separate components, which makes the process of assembly somewhat susceptible to error.

It is therefore an object of the present disclosure to construct a structural unit for power modules that is simple, requiring only few components, cools the power modules efficiently and is easily assembled.

### SUMMARY

The object is achieved with a structural unit for power modules including at least one power module, including a cooling channel having an inlet and outlet, wherein the cooling channel is formed by a lower half-shell and an upper half-shell, and wherein the power electronics system has cooling fins that protrude through a respective cut-out into the cooling channel, wherein the cooling channel is closed in a materially bonded manner between the power module and the upper half-shell, and the lower half-shell and the upper half-shell are produced by deep-drawing, at least one bridging piece interconnecting them.

The structural unit for power modules has advantages, as the materially bonded connection provides the sealing function, eliminating the need for seals.

The design makes it possible to dispense with fastening structures and fastening elements for the power modules, as the components are also held in place mechanically by the materially bonded connection, and do not need to be additionally fastened.

A materially bonded connection is characterized by the fact that the components to be connected are connected to each other by atomic or molecular bonds. This is also the reason for the fact that this type of connection can only be undone by destroying the connection. Within this group, the joining methods may be further differentiated according to whether the connection is made using intrinsic or extrinsic additive materials. Soldering, welding and bonding are the best-known joining methods in this group.

The reduction of obstacles in the coolant flow in the cooling channel results in less “unnecessary” pressure loss.

Due to the thin-walled nature of the metallic, deep-drawn half-shell, there is only a minimal influence on the flow at the joint to the power module. The coolant does not have to overcome any constrictions. As a result, there is more pressure loss available, which occurs at the cooling structures of the power module and improves thermal dissipation.

The cooling channel may be produced from a single metal-plate deep-drawn/stamped part, which reduces the number of components. Only one deep-drawn component needs to be handled in the constructing of the assembly.

It is advantageous that the at least one bridging piece extends at least on the outer circumference in the region of a frame of the upper half-shell. The bridging piece serves to route the two half-shells in relation to each other, such that precise overlapping is effected during assembly.

In one embodiment, two bridging pieces overlap, in relation to the length of the upper half-shell, a length that is less than the length of the upper half-shell.

In a further embodiment, two bridging pieces overlap, in relation to the length of the upper half-shell, a length that is greater than the non-overlapped length of the upper half-shell.

Another design uses a bridging piece that overlaps the total length of the upper half-shell.

It is advantageous that the upper half-shell and the lower half-shell are connected to each other with a positive or materially bonded connection along the outer edge of the two half-shells.

The materially bonded connection in this case is a soldered, welded or adhesively bonded connection.

The materially bonded connection between the power module and the upper half-shell is formed via a circumferential contact point on the substrate of the power modules.

The object is also achieved with an assembly method for the structural unit for power modules including the following steps:
producing a lower half-shell and an upper half-shell of the cooling channel with at least one connecting bridging piece,
producing the cooling channel by bending the half-shells toward each other,
inserting power modules, with cooling fins already attached to them, into cut-outs in the upper half-shell of the cooling channel,
connecting the upper and lower half-shells in a sealing manner along their outer edge, also along the at least one bridging piece,
connecting the upper half-shell to the power modules in a sealing manner along the frame of the cut-outs.

The sequence of the last two steps may also be reversed, depending on how the connections are produced.

Alternatively, the assembly method used is:
producing a lower half-shell and an upper half-shell of the cooling channel with at least one connecting bridging piece,
producing the cooling channel by bending the half-shells toward each other,
inserting cooling fins into cut-outs in the upper half-shell of the cooling channel,
applying solder pads to the cooling fins,
connecting the upper half-shell to the power modules in a sealing manner along the frame of the cut-outs, and simultaneously connecting the cooling fins to the power modules,
connecting the upper and lower half-shells in a sealing manner along their outer edge, before or after the last step.

### DRAWINGS

The present disclosure is described below by way of example with reference to the accompanying drawings.

FIG. 1 shows a schematic representation of half-shells for the formation of a cooling channel,

FIG. 2 shows the finished housing,

FIGS. 3 to 5 show a plurality of variants of the housing,

FIG. 6 shows a cross-section through a structural unit for power modules,

FIG. 7 shows a view of cooling fins in the opened housing,

FIG. 8 shows a view of the opened housing from above the power modules.

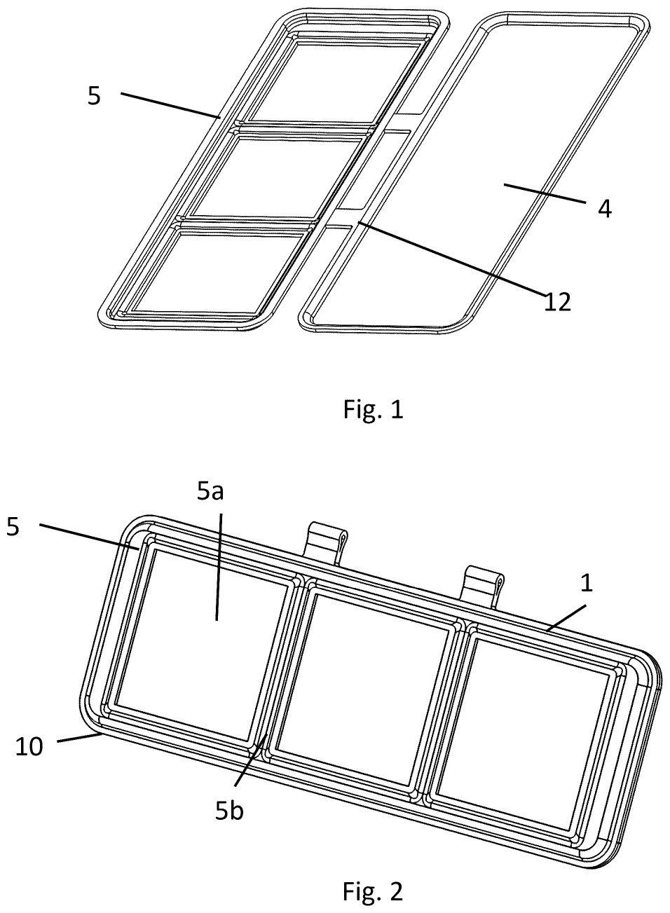

### DETAILED DESCRIPTION

The present disclosure is a design of a structural unit 1 for power modules 2, composed substantially of two main components, a lower half-shell 4 and an upper half-shell 5. Both half-shells are composed of a metal plate, which may be deep-drawn in one piece to form the final shape. The metal plates of the lower half-shell 4 and an upper half-shell 5 are connected to each other via two bridging pieces 12.

In FIG. 2, a top view of the upper half-shell 5 shows an almost rectangular face. As viewed toward its face, the upper half-shell 5 is flat, but has three cut-outs 5a. The cut-outs 5a are each surrounded by a raised frame 5b protruding from the face of the upper half-shell.

The bridging pieces 12 for connecting the two half-shells 4, 5 are bent over in the final state and form a hinge that can be used once.

The outer dimensions and the outer edge 10 of the upper half-shell 5 match those of the lower half-shell 4. Consequently, when the bridging pieces 12 are folded together, the metal-plate face of the upper half-shell 5 bears on an outer circumferential flange of the lower half-shell 4.

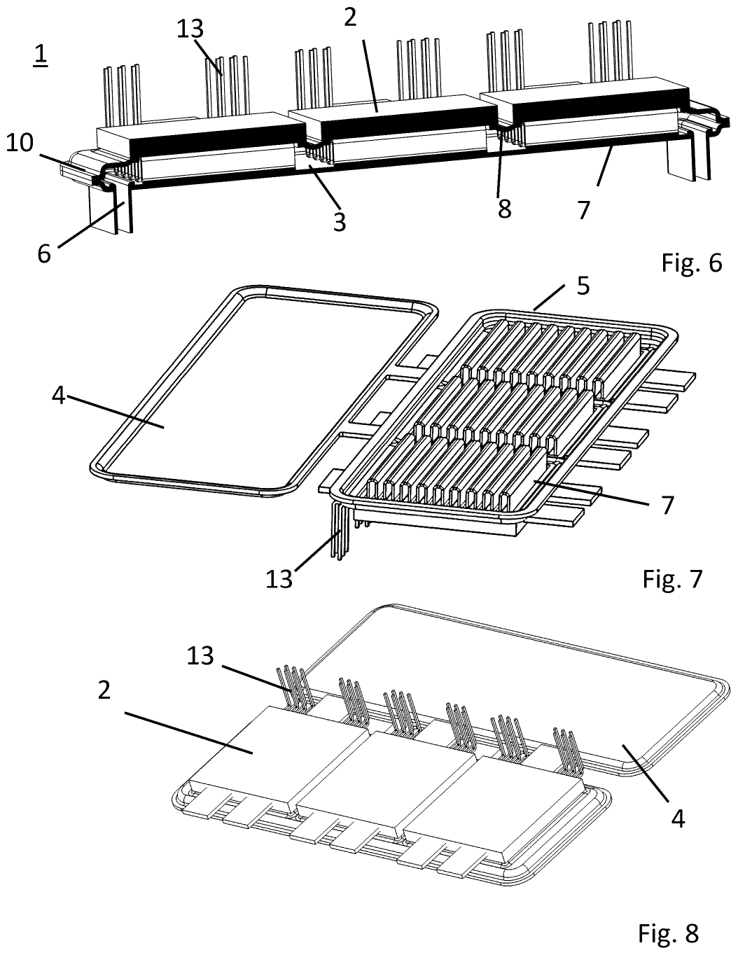

The two half-shells 4, 5 are joined together by a suitable method such as braze welding, laser welding, flanging, etc. and, as shown in FIG. 6, form a closed body that has three cut-outs 5a and inlets and outlets 6. Closing of the two half-shells is effected without the use of seals. The different methods for closing the two half-shells to form the cooling channel 3 are also effected circumferentially at the sites of the outer edge 10, which is interrupted by the bridging pieces 12.

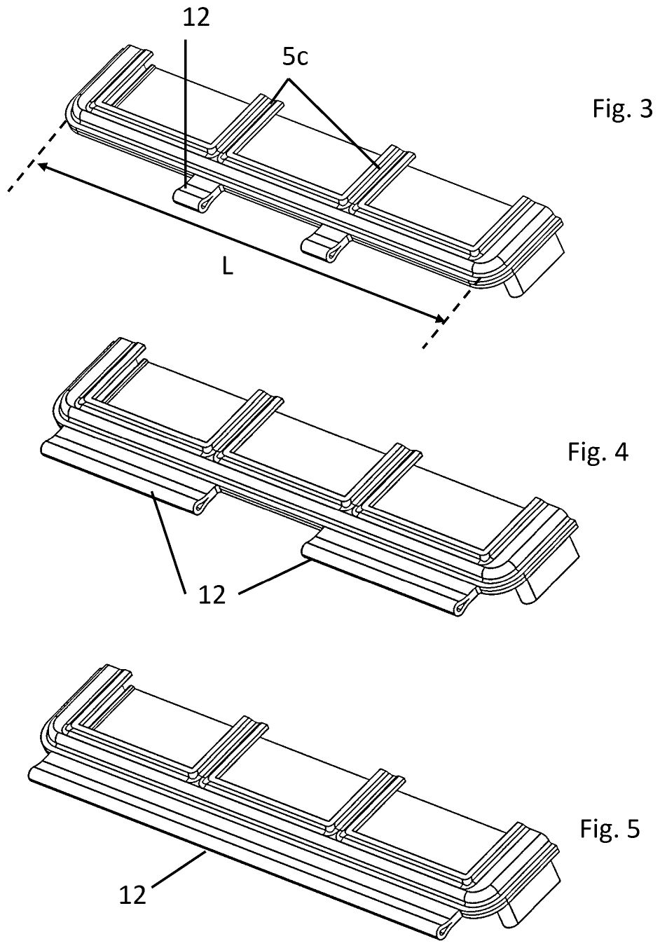

Embodiments are represented in FIGS. 3 to 5. FIG. 3 has narrow bridging pieces, of a first width, being a partial length in relation to the total length L of the structural unit L, while an embodiment with wider bridging pieces 12, of a second width, being a partial length in relation to the total length L, is represented in FIG. 4. The bridging pieces 12 in this case are attached at least in the region 5c of the frame 5b, which includes the cut-outs 5a. In the embodiment according to FIG. 4, the bridging pieces 12 extend from the outer edge of the narrow legs of the outer edge 10 to the regions 5c and overlap the majority of the total length L, being a combined length of twice the second width.

In FIG. 5, there is a single bridging piece 12 that extends along the total length L.

The power module 2 components are inserted into the cut-outs 5a in the upper half-shell 5. The cooling structure in the form of the cooling fins 7 of the power modules 2 protrudes into the cooling channel 3. The cooling fins 7 in this case extend to the lower half-shell 4 along the height of the cooling channel 3.

In the next step, the power modules 2 are tightly connected to the upper half-shell 5 in order to close the cooling channel 3. For this purpose, the lower half-shell 4 is pivoted onto the upper half-shell, as can be seen from FIG. 7. The contacts 13 of the power modules do not interfere with this movement of the lower half-shell 4, as they extend on the side that faces away.

An important aspect of the present disclosure is then the connection between power module 2 and the upper half-shell 5 of cooling channel 3.

The connection is produced by a soldered joint, e.g. by soft soldering. The soldered joint 8 extends along the frame 5b of the upper half-shell 5 and along the substrate of the power modules 2, around the cooling body of the power modules 2. The power modules 2 have a printed circuit board on which the actual semiconductor components are mounted. The printed circuit board is thermally connected to the terminal connections of the cooling fins 7.

Alternatively, an adhesive connection 8 may be used instead of soldering. In this case, a frame-like recess around the cut-outs 5 is suitable for creating a defined adhesive layer thickness.

The cooling channel 3 is thus closed in a materially bonded manner without the use of a seal. The inlet and outlet 6 are also connected to the lower half-shell in a materially bonded manner. If necessary, this connection may also be made together with the connecting of the lower and upper half-shell.

Following assembly, the bridging pieces 12 form tabs that may be used to screw the structural unit 1 into the inverter.

The assembly method for the structural unit for power modules is thus effected in the steps:
producing a lower half-shell and the upper half-shell of the cooling channel with bridging pieces,
bending the two half-shells toward each other,
connecting the upper and lower half-shells in a sealing manner along their entire outer edge,
inserting the power modules, with cooling fins already attached to them, into cut-outs in the upper half-shell of the cooling channel,
connecting the power modules to the upper half-shell in a sealing manner.

The alternative assembly method according to the present disclosure for the structural unit for power modules 1 is thus effected in the following steps:
producing a lower half-shell and the upper half-shell of the cooling channel with bridging pieces,
bending the two half-shells toward each other,
inserting cooling fins 7 into the cut-outs in the upper half-shell 5 of the cooling channel,
applying solder pads to the cooling fins 7,
connecting the upper half-shell 5 to the power modules 2 in a sealing manner along the frame 5b of the cut-outs 5a and simultaneously connecting the cooling fins 7 to the power modules 2,
connecting the upper and lower half-shells 4, 5 in a sealing manner along their outer edge 10, before or after the last step.

### LIST OF REFERENCE SIGNS

1 structural unit for power modules
2 power module
3 cooling channel
4 lower half-shell cooling channel
5 upper half-shell cooling channel
5a cut-outs
5b frame
5c region
6 inlet and outlet connection piece
7 cooling fin
8 adhesively bonded/soldered/welded connection
10 outer edge
12 webs

What is claimed is:

1. A structural unit for power modules comprising:
at least one power module,
a cooling channel having an inlet and outlet, wherein the cooling channel is formed by a lower half-shell and an upper half-shell, and
cooling fins of the power module that protrude through a respective cut-out of the upper half-shell into the cooling channel,
wherein the cooling channel is closed in a materially bonded manner between the power module and the upper half-shell, and
wherein the lower half-shell and the upper half-shell are produced by deep-drawing,
wherein at least one bridging piece interconnects the lower half-shell and the upper half-shell.

2. The structural unit for power modules as claimed in claim 1, wherein the at least one bridging piece extends at least on an outer edge of the upper half-shell and the lower half-shell in a region of a frame of the upper half-shell.

3. The structural unit for power modules as claimed in claim 1, wherein the at least one bridging piece comprises two bridging pieces overlap along a length, that is less than a total length of the upper half-shell.

4. The structural unit for power modules as claimed in claim 1, wherein the at least one bridging piece comprises two bridging pieces that overlap along a length that is greater than a non-overlapped length out of a total length of the upper half-shell.

5. The structural unit for power modules as claimed in claim 1, wherein a bridging piece overlaps along a total length of the upper half-shell.

6. The structural unit for power modules as claimed in claim 1, wherein the upper half-shell and the lower half-shell are connected to each other with a positive or materially bonded connection along an outer edge of the lower and upper half-shells.

7. The structural unit for power modules as claimed in claim 1, wherein the lower half-shell has an outer flange on an outer edge thereof for connection to the upper half-shell.

8. The structural unit for power modules as claimed in claim 1, wherein the materially bonded connection is a soldered, welded or adhesively bonded connection.

9. The structural unit for power modules as claimed in claim 1, wherein the materially bonded connection between the power module and the upper half-shell is formed via a circumferential contact point on a substrate of the power modules.

10. An assembly method for a structural unit for power modules, the method comprising:
producing a lower half-shell and an upper half-shell of a cooling channel with at least one connecting bridging piece interconnecting the lower half-shell and the upper half-shell,
producing the cooling channel by bending the lower and upper half-shells toward each other,
inserting power modules, with cooling fins attached thereto, into cut-outs in the upper half-shell of the cooling channel,
connecting the upper and lower half-shells in a sealing manner along respective outer edges thereof, wherein the upper and lower half-shells are also connected along the at least one bridging piece,
connecting the upper half-shell to the power modules in a sealing manner along a frame of the cut-outs.

11. An assembly method for a structural unit for power modules, the method comprising:
producing a lower half-shell and an upper half-shell of a cooling channel with at least one connecting bridging piece interconnecting the lower half-shell and the upper half-shell,
producing the cooling channel by bending the lower and upper half-shells toward each other,
inserting cooling fins into cut-outs in the upper half-shell of the cooling channel,
applying solder pads to the cooling fins,
connecting the upper half-shell to the power modules in a sealing manner along a frame of the cut-outs, and simultaneously connecting the cooling fins to the power modules,
connecting the upper and lower half-shells in a sealing manner along respective outer edges thereof.

12. The assembly method of claim 11, wherein the upper half-shell is connected to the lower half-shell along the respective outer edges before the upper half-shell is connected to the power modules.

13. The assembly method of claim 11, wherein the upper half-shell is connected to the lower half-shell along the respective outer edges after the upper half-shell is connected to the power modules.

14. The assembly method of claim 10, wherein the upper half-shell is connected to the lower half-shell along the respective outer edges before being connected to the power modules.

15. The assembly method of claim 10, wherein the upper half-shell is connected to the lower half-shell along the respective outer edges after being connected to the power modules.

16. The structural unit for power modules as claimed in claim 1, wherein the upper half-shell and the lower-half shell are a single unitary one-piece structure.

17. The structural unit for power modules as claimed in claim 1, wherein the lower half-shell and the upper half-shell are made of a metal plate, wherein the metal plate is deep drawn in one-piece to form a final shape.

18. The structural unit for power modules as claimed in claim 1, wherein the upper half-shell 5 has a generally flat rectangular face, wherein each respective cut-out is surrounded by a raised frame protruding from the face of the upper half-shell.

19. The structural unit for power modules as claimed in claim 1, wherein the lower half-shell and the upper half-shell are connected without separate seals therebetween.
